(19) United States
(12) Patent Application Publication
(10) Pub. No.: US 2007/0235221 A1
(43) Pub. Date: Oct. 11, 2007

(54) METAL SHIELDING APPARATUS

(76) Inventor: Jia-Hao Chang, Sinjhuang City (TW)

Correspondence Address: Anthony R. Barkume, 20 Gateway Lane, Manorville, NY, 11949, US

(21) Appl. No.: 11/535,236

(22) Filed: Sep. 26, 2006

(30) Foreign Application Priority Data
Apr. 11, 2006 (TW) 095206121

(51) Int. Cl. H05K 9/00

(52) U.S. Cl. 174/382; 174/377; 174/387

(57) ABSTRACT

The present invention is a metal shielding apparatus; it includes a cover shielding and a bottom shielding. The cover shielding has a number of holes while the bottom shielding has a number of jutted points. The holes and the jutted points can be used for alignment when combining these two covers. And there is at least one raised part among the jutted points for a better fitting of the cover and bottom shieldings and further prevents from the looseness. Furthermore, the holes, jutted points and raised parts can also be setup on the cover and the bottom shieldings interchangeably for the same effect.

### FIELD OF THE INVENTION

The present invention relates to a shielding, and more particularly to a metal shielding apparatus.

### BACKGROUND OF THE INVENTION

The metal shielding apparatus can be used to protect from the electro-magnetic waves. We can use this metal shielding apparatus to shield against the electro-magnetic waves commonly founded with high radio-frequency electronics.

For example, the cellular phone is an electronic product with high radio frequency. In order to protect from exposure to the electro-magnetic waves, we would normally put a metal shielding apparatus on a internal circuit board. Hence, we might protect the users from the adverse effect of the electro-magnetic waves.

The conventional metal shielding apparatus is combined with cover and bottom shieldings with holes and jutted points to align. There are some drawbacks for such design:

1. There may be leaks of the cover over a period of time; thus, the electro-magnetic waves will probably leak out of the shieldings.

2. The loosing metal shielding apparatus will probably shake. It may produce the metal clack sound when using. This tiny noise will hence lower the electronic products'quality. So the users will feel uncomfortable when they use the products, or even think that the products are broken. It is the focus of the present invention to eliminate the above drawbacks and promote the quality of the products by ensuring that the metal shielding apparatus is tightly connected over a long period of time.

### SUMMARY OF THE INVENTION

The objective of the present invention is to offer an innovative and advanced metal shielding apparatus. By using the jutted point in a distinctive way, it will let the combination of metal shielding apparatus to be more secure without looseness over a long period time or in a crash.

According to the present invention, a metal shielding apparatus comprises:

a cover shielding has a hanging side with a plurality of holes;

a bottom shielding has a side with a plurality of jutted points aligning with the holes on the cover shielding; the side of the bottom shielding even has at least a raised part for a better fitting of the cover shielding and the bottom shielding to prevent from looseness.

In accordance with one aspect of the present invention, the metal shielding apparatus is used on a circuit board to prevent from the electro-magnetic interference (EMI).

In accordance with one aspect of the present invention, the metal shielding apparatus is used on a circuit board of a mobile phone.

In accordance with one aspect of the present invention, the raised part is located among the jutted points.

In accordance with one aspect of the present invention, the frame connects makes a complete housing with the cover shielding.

According the present invention, another metal shielding apparatus comprises:

A cover shielding has a hanging side with a plurality of jutted points;

A bottom shielding has a side with a plurality of holes for aligning with the jutted points on the cover shielding as a means for combining the cover shielding and the bottom shielding; the hanging side of the cover shielding even has at least a raised part to make the combination of the cover shielding and the bottom shielding to be better fitted and prevent from looseness.

In accordance with one aspect of the present invention, the metal shielding apparatus is used on a circuit board to prevent from the electro-magnetic interference (EMI).

In accordance with one aspect of the present invention, the metal shielding apparatus is used on a circuit board of a cellular phone.

In accordance with one aspect of the present invention, the raised part is located among the jutted points.

In accordance with one aspect of the present invention, the bottom shielding is a frame; the frame connects makes a complete housing to the cover shielding.

The present invention may be best understood through the following description with reference to the accompanying drawings, in which:

### BRIEF DESCRIPTION OF THE DRAWINGS

FIG. 1 is an illustration of the metal shielding apparatus;

FIG. 2 is an illustration of assembling the metal shielding apparatus;

FIG. 3 is an illustration of the metal shielding apparatus and the circuit board.

### DETAILED DESCRIPTION OF THE PREFERRED EMBODIMENT

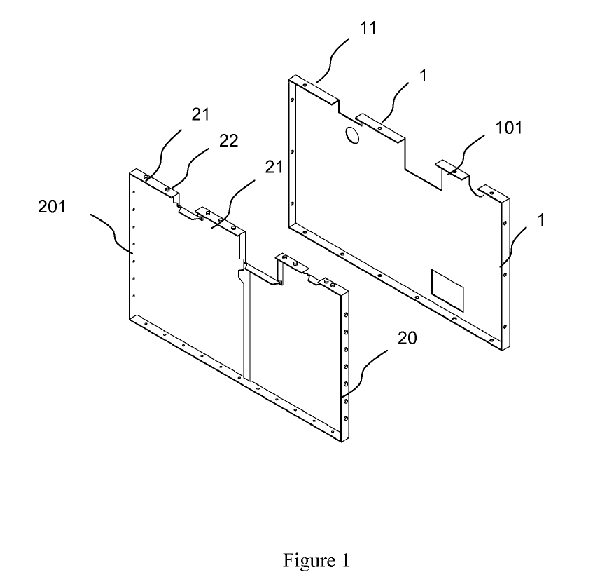

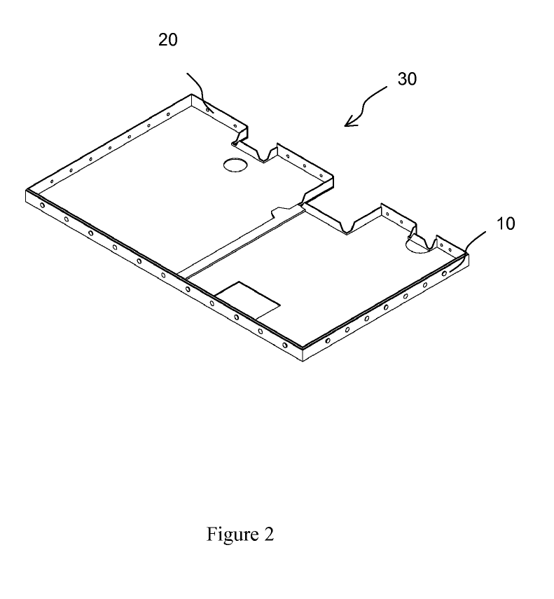

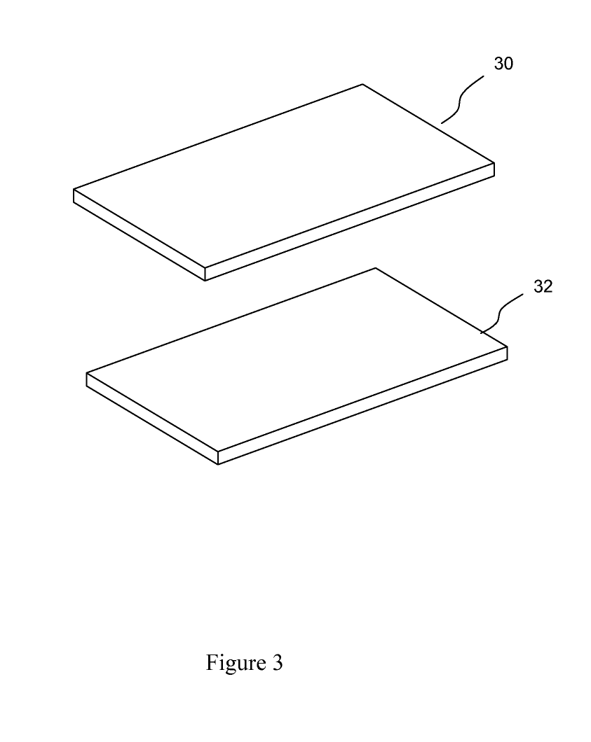

FIG. 1 is an illustration of the metal shielding apparatus. It includes a cover shielding (10), a bottom shielding (20), holes (11), jutted points (21), raised part (22), a hanging side (101) from the cover shielding, a side (201) from the bottom shielding. FIG. 2 is an illustration of assembling the cover and bottom covers. It includes a complete housing (30), a cover shielding (10) and a bottom shielding (20). FIG. 3 is an illustration of metal shielding apparatus and the circuit board. It includes a complete housing (30) and a circuit board (32).

The metal shielding apparatus in the present invention has a cover (10) and a bottom shielding (20). The combination of these two parts can be achieved by connecting the holes (11) and jutted points (21). It can also be achieved by connecting the raised part (22) for a even tighter connection of a cover shielding (10) and a bottom shielding (20). The principle of this design is to make the cover and bottom shielding better fitted by connecting the raised part (22) and the hanging side of the cover shielding. The raised part (22) can be one or many and can be in any shapes. The purpose of the raised part is to have a better fitting of the cover and the bottom shielding. Furthermore, the raised part can be inserted among the holes or among the jutted points on the cover shielding if one desires jutted points better than holes. Above all, the raised part can be on the cover or bottom shielding or both and so are the jutted points and aligning holes. The design of positioning the aligning holes, jutted points, raised parts is the main object of the present invention.

Of course, the combination of the cover shielding (10) and the bottom shielding (20) can be a complete housing (30). The complete housing can be positioned on any circuit board (32) in any types of electronic products from the interference of any electro-magnetic waves.

The metal shielding apparatus in the present invention can make the fitting of the cover and the bottom shieldings tightly combined. And it will not cause any looseness to affect the overall quality of the electronic products over a long period of time when using. It is designed to be efficient and novel. We can easily modify its design, such as the appearances or the position of the holes, raised parts and jutted points to be used in any type of electronic products, e.g., mobile phones, TV, PDA, notebook, etc. As long as we use the raised parts on the cover or the bottom shieldings to bring the effect of better fitting, they are all within the scope of this project.

While the invention has been described in terms of what are presently considered to be the most practical and preferred embodiments, it is to be understood that the invention needs not being limited to the disclosed embodiment. On the contrary, it is intended to cover various modifications and similar arrangements included within the spirit and scope of the appended claims that are to be complied with the broadest interpretation so as to encompass all such modifications and similar structures.

What is claimed is:

1. A metal shielding apparatus comprising:
a cover shielding has a hanging side with a plurality of holes;
a bottom shielding has a side with a plurality of jutted points aligning with the holes on the cover shielding; said side of said bottom cover even has at least a raised part for a better fitting of said cover shielding and said bottom shielding to prevent from looseness.

2. The metal shielding apparatus according to claim 1 wherein said metal shielding apparatus is used on a circuit board to prevent from the electro-magnetic interference (EMI).

3. The metal shielding apparatus according to claim 1 wherein said metal shielding apparatus is used on a circuit board of a mobile phone.

4. The metal shielding apparatus according to claim 1 wherein said raised part is located among said jutted points.

5. The metal shielding apparatus according to claim 1 wherein said bottom shielding is a frame; said frame connects makes a complete housing to said cover shielding.

6. A metal shielding apparatus comprising:
A cover shielding has a hanging side with a plurality of jutted points;
A bottom shielding has a side with a plurality of holes for aligning with said jutted points on said cover shielding as a means for combining said cover shielding and said bottom shielding; said hanging side of said cover shielding even has at least a raised part to make the combination of said cover shielding and said bottom shielding a better fitting and prevent from looseness.

7. The metal shielding apparatus according to claim 6 wherein said metal shielding apparatus is used on a circuit board to prevent from the electro-magnetic interference (EMI).

8. The metal shielding apparatus according to claim 6 wherein said metal shielding apparatus is used on a circuit board of a cellular phone.

9. The metal shielding apparatus according to claim 6 wherein said raised part is located among said jutted points.

10. The metal shielding apparatus according to claim 6 wherein said bottom shielding is a frame; said frame connects to said cover shielding to make a complete housing.
